(19) United States
(12) Patent Application Publication
(10) Pub. No.: US 2014/0345928 A1
(43) Pub. Date: Nov. 27, 2014

(54) ELECTRONIC PART, ELECTRONIC APPARATUS, AND MOVING OBJECT

(71) Applicant: Seiko Epson Corporation, Tokyo (JP)

(72) Inventor: Yugo KOYAMA, Ina (JP)

(73) Assignee: Seiko Epson Corporation, Tokyo (JP)

(21) Appl. No.: 14/285,021

(22) Filed: May 22, 2014

(30) Foreign Application Priority Data
May 27, 2013 (JP) 2013-110615
Mar. 18, 2014 (JP) 2014-054495

(51) Int. Cl. H05K 1/02; H05K 1/18; H05K 1/11

(52) U.S. Cl. CPC H05K 1/0271; H05K 1/111; H05K 1/181
USPC 174/260; 174/261

(57) ABSTRACT

An electronic part includes amount substrate, a circuit substrate, a pad disposed on the circuit substrate, a bump that connects the mount substrate and the pad to each other, and a surface protection film that extends from a surface of the pad via an outer circumferential edge of the pad to a surface of the circuit substrate and has at least two openings adjacent to each other on the pad. The length equal to one-half the shortest distance from an end of one of the adjacent openings to an end of the other opening is smaller than the length of the shortest distance from the outer circumferential edge of the pad to the end of each of the openings, and the bump is provided in each of the two openings and layered on the surface protection film in a plan view.

### BACKGROUND

1. Technical Field

The present invention relates to an electronic part, an electronic apparatus, and a moving object.

2. Related Art

To reduce the size and thickness of a variety of electronic apparatus, there is a surface mounting technology of related art for mounting a circuit substrate having onboard ICs and other components on a mount substrate with the circuit substrate facing downward. The mount substrate and the circuit substrate are electrically connected to each other via bumps or any other metal portions formed between a pad provided on the mount substrate and a pad on the circuit substrate. FIGS. 12A and 12B show the structure of a bump formed on a pad provided at a single location on an electronic part. FIG. 12A is a plan view, and FIG. 12B is a cross-sectional view taken along the line G-G in FIG. 12A. An electronic part 101 has a circuit substrate 110 and a mount substrate 130, and in a state before the circuit substrate 110 is mounted on the mount substrate 130, a surface protection film 116, which covers the active surface of the circuit substrate 110 on which a pad 112 and a lead portion 114 are provided, is partially opened to expose the pad 112. A rectangular bump 120 is bonded via a barrier metal 122 to the pad 112 through an opening 118 of the surface protection film 116. The circuit substrate 110 is then bonded onto the mount substrate 130 by inverting the circuit substrate 110 shown in FIG. 12B upside down, placing the bump 120 on a pad 132 provided on the mount substrate 130, and bonding and electrically connecting the bump 120 to the pad 132 on the mount substrate 130 in a thermocompression bonding process or an ultrasonic-assisted thermocompression bonding process, as shown in FIG. 13B, which is a cross-sectional view taken along the line H-H in FIG. 13A.

The bonding structure of the electronic part 101 described above is, however, problematic in that when the electronic part 101 is operated at a high frequency, a signal passing through the bump is greatly shifted to the outer circumference of the bump due to a skin effect, resulting in a substantial increase in resistance to the passage of current and hence an increase in signal power loss.

To solve the problem described above, JP-A-11-195666 discloses a method for reducing the loss in signal power in the bump 120 by dividing the bump 120, which is connected to the pad 112 in the opening 118 of the surface protection film 116, into a plurality of portions to increase the circumferential length of the bump 120 although the bonding area of the bump is unchanged.

When the bump 120 is bonded to the pad 132 on the mount substrate 130 in the compression bonding process, however, a large compression bonding load that is offset because the formed bump 120 is not perpendicular to the bonding surface of the mount substrate 130 undesirably causes the compressed bump 120 to extend off the circumferential edge of the pad 112 by a length D (shown in FIG. 13B) in the bonding process. As described above, the bump 120 that extends off the region of the pad 112 and reaches the surface protection film 116 on the circuit substrate 110 is likely to cause breakage of the surface protection film 116 due to thermal or residual stress in the compression binding process, possibly resulting in corrosion of an electrode material of which the pad 112 is made due, for example, to moisture that enters through the broken portion and hence a significant decrease in reliability.

### SUMMARY

An advantage of some aspects of the invention is to solve at least a part of the problems described above, and the invention can be implemented as the following forms or application examples.

### Application Example 1

This application example is directed to an electronic part including a mount substrate, a circuit substrate, a pad provided on the circuit substrate, a bump that connects the mount substrate and the pad to each other, and a surface protection film that extends from a surface of the pad via an outer circumferential edge of the pad to a surface of the circuit substrate and has at least two openings adjacent to each other on the pad. The length equal to one-half the shortest distance from an end of one of the adjacent openings to an end of the other opening is smaller than the shortest distance from the outer circumferential edge of the pad to the end of each of the openings, and the bump is provided in each of the two openings and layered on the surface protection film in a plan view.

According to this application example, a plurality of openings are provided in the surface protection film on the pad formed on the circuit substrate, and the length equal to one-half the shortest distance between the ends of the adjacent openings is smaller than the shortest distance from the outer circumferential edge of the pad to the end of each of the openings. In this configuration, when the circuit substrate is bonded to the mount substrate, and even when each of the bumps is so compressed in a compression bonding process that the outer circumference of the compressed bump spreads and comes into contact with an adjacent bump, the outer circumference of the bump does not come into contact with the outer circumferential edge of the pad, whereby a situation in which the bump spreads to a portion close to the outer circumference of the pad can be avoided. The compressed bumps do not extend off the region of the pad as described above, which is advantageous in that the surface protection film will not be broken and a highly reliable electronic part is provided.

Further, a plurality of openings are provided in the surface protection film on the pad formed on the circuit substrate, and one bump is formed in each of the openings. As a result, a plurality of bumps are provided. The resistance to the passage of current due to a skin effect according to the circumferential length of each of the bumps can therefore be reduced, whereby an electronic part that loses only a small amount of signal power in the bumps is provided.

### Application Example 2

This application example is directed to the electronic part according to the application example described above, wherein the bumps have a rectangular shape and are so arranged that the distance between the outer circumferential edge of the pad and a corner of each of the openings is minimized.

According to this application example, the pad formed on the circuit substrate and the openings in the surface protection film each have a rectangular shape and are so arranged that the distance between the outer circumferential edge of the pad and an inner corner of each of the openings is minimized, whereby when the bumps are compressed, the corner of the rectangular bump is unlikely to spread or extend off the pad, which is advantageous in that the degree of breakage of the surface protection film can be lowered and a highly reliable electronic part is provided.

### Application Example 3

This application example is directed to the electronic part according to the application example described above, wherein the bumps are provided in a plating process.

According to this application example, forming the bumps in a plating process allows single-step formation of the bumps on a large substrate on which a plurality of circuit substrates are formed, whereby the bumps have a uniform height, variation in the amount of compression is small at the time of mounting, and the cost can be reduced as compared with bump formation using a bump bonder.

### Application Example 4

This application example is directed to the electronic part according to the application example described above, wherein the bumps adjacent to each other are in contact with each other.

According to this application example, in which the outer circumference of each of the bumps is compressed and spreads onto the surface protection film between the bump and an adjacent bump and the spread outer circumferences come to contact with each other. As a result, the compressed bumps can cover broken pieces and other defective portions of the surface protection film that are produced when the surface protection film between the bumps is broken due to stress produced in the compression bonding process or other types of external stress, which is advantageous in that the broken pieces of the surface protection film are unlikely to be released outside and hence a highly reliable electronic part is provided.

### Application Example 5

This application example is directed to the electronic part according to the application example described above, wherein the openings have sizes different from each other.

According to this application example, since the openings have sizes different from each other, openings having a smaller size can be disposed along the periphery of the pad, and an opening having a larger size can be disposed in a central portion of the pad. As a result, when the bumps are bonded to the mount substrate, the bumps having a smaller size and formed in the openings disposed along the periphery of the pad are compressed but extend off the region of the pad only by a small amount, whereby breakage of the surface protection film due to the extend-off bumps can be avoided. On the other hand, the bump having a larger size and formed in the opening disposed in the central portion of the pad is compressed, and the outer circumference of the bump spreads widely but does not reach the outer circumference of the pad, which is advantageous in that the surface protection film will not be broken and hence the bonding strength between the bumps and the mount substrate can be increased.

### Application Example 6

This application example is directed to the electronic part according to the application example described above, wherein the openings are located in at least three positions.

According to this application example, in which at least three openings are provided in the surface protection film formed on the pad, the greater the number of openings, the greater the bonding strength because the bonding surface area increases. Further, since a plurality of bumps are provided, the resistance to the passage of current due to a skin effect according to the circumferential length of each of the bumps can be reduced, whereby an electronic part that has increased bonding strength between the bumps and the mount substrate and loses only a small amount of signal power in the bumps is advantageously provided.

### Application Example 7

This application example is directed to the electronic part according to the application example described above, wherein the electronic part further includes a resonator element, and the resonator element is disposed on the mount substrate and electrically connected to the circuit substrate.

According to this application example, disposing the resonator element on the mount substrate and electrically connecting the resonator element to the circuit substrate allows formation of an oscillation device as an electronic part. When the mount substrate on which the oscillation device is disposed is bonded to the circuit substrate, each of the bumps is compressed and the outer circumference thereof spreads onto the surface protection film between the bump and an adjacent bump, whereby the surface protection film between the bumps will not be broken due to external stress other than stress produced in the compression bonding process, and the resistance to the passage of current due to a skin effect according to the circumferential length of each of the bumps can be reduced. An electronic part that has high reliability and loses only a small amount of signal power in the bumps is therefore advantageously provided.

### Application Example 8

This application example is directed to an electronic apparatus including the electronic part according to the application example described above.

This application example provides an advantageous effect of providing an electronic apparatus including an electronic part that excels in mechanical strength and has high reliability.

### Application Example 9

This application example is directed to a moving object including the electronic part according to the application example described above.

This application example provides an advantageous effect of providing a moving object including an electronic part that excels in mechanical strength and has high reliability.

### BRIEF DESCRIPTION OF THE DRAWINGS

The invention will be described with reference to the accompanying drawings, wherein like numbers reference like elements.

FIGS. 1A and 1B are schematic configuration diagrams of a pad portion provided on a circuit substrate of an electronic part according to a first embodiment of the invention. FIG. 1A is a plan view, and FIG. 1B is a cross-sectional view taken along the line A-A.

FIGS. 2A and 2B are schematic configuration diagrams showing the pad portion in a state in which the circuit substrate of the electronic part according to the first embodiment of the invention is mounted on a mount substrate thereof. FIG. 2A is a plan view, and FIG. 2B is a cross-sectional view taken along the line B-B.

FIGS. 3A and 3B are schematic configuration diagrams of a pad portion provided on a circuit substrate of an electronic part according to a second embodiment of the invention. FIG. 3A is a plan view, and FIG. 3B is a cross-sectional view taken along the line C-C.

FIGS. 4A and 4B are schematic configuration diagrams showing the pad portion in a state in which the circuit substrate of the electronic part according to the second embodiment of the invention is mounted on a mount substrate thereof. FIG. 4A is a plan view, and FIG. 4B is a cross-sectional view taken along the line D-D.

FIGS. 5A and 5B are schematic configuration diagrams of a pad portion provided on a circuit substrate of an electronic part according to a third embodiment of the invention. FIG. 5A is a plan view, and FIG. 5B is a cross-sectional view taken along the line E-E.

FIGS. 6A and 6B are schematic configuration diagrams showing the pad portion in a state in which the circuit substrate of the electronic part according to the third embodiment of the invention is mounted on a mount substrate thereof. FIG. 6A is a plan view, and FIG. 6B is a cross-sectional view taken along the line F-F.

FIG. 7 is a cross-sectional view showing a schematic configuration of an oscillation device as an example of an electronic part according to a fourth embodiment of the invention.

FIG. 8 is a perspective view showing the configuration of a mobile (or notebook) personal computer as an electronic apparatus including the electronic part according to any of the embodiments of the invention.

FIG. 9 is a perspective view showing the configuration of a mobile phone (including PHS) as an electronic apparatus including the electronic part according to any of the embodiments of the invention.

FIG. 10 is a perspective view showing the configuration of a digital camera as an electronic apparatus including the electronic part according to any of the embodiments of the invention.

FIG. 11 is a perspective view showing the configuration of an automobile as a moving object including any of the electronic parts according to the embodiments of the invention.

FIGS. 12A and 12B are schematic configuration diagrams of a pad portion provided on a circuit substrate of an electronic part of related art. FIG. 12A is a plan view, and FIG. 12B is a cross-sectional view taken along the line G-G.

FIGS. 13A and 13B are schematic configuration diagrams of the pad portion in a state in which the circuit substrate of the electronic part of related art is mounted on a mount substrate. FIG. 13A is a plan view, and FIG. 13B is a cross-sectional view taken along the line H-H.

### DESCRIPTION OF EXEMPLARY EMBODIMENTS

Embodiments of the invention will be described below in detail with reference to the drawings.

### Electronic Part

### First Embodiment

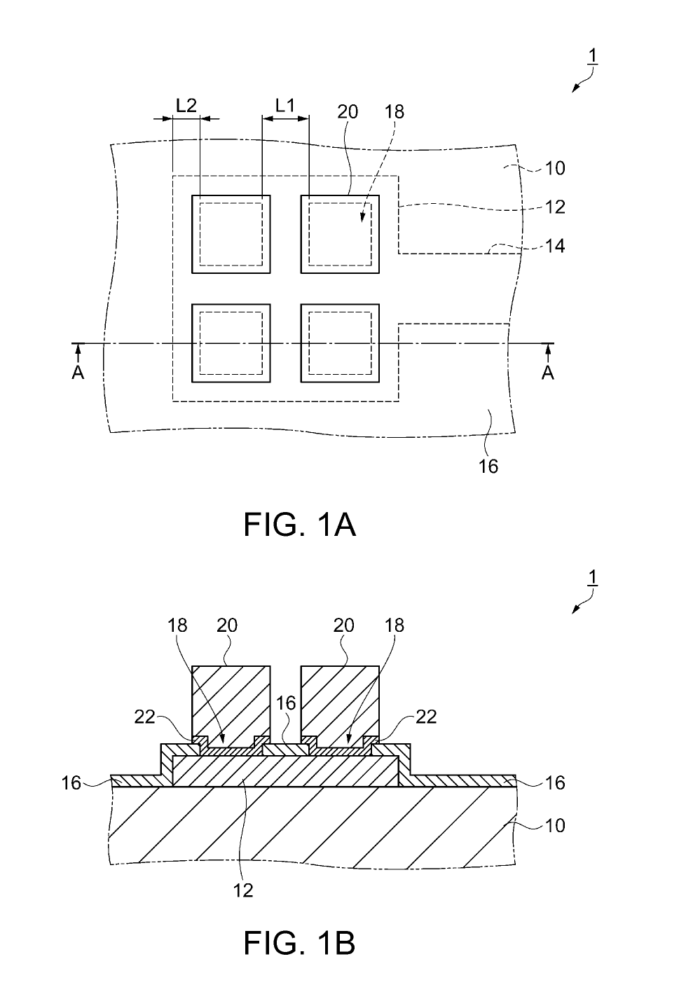

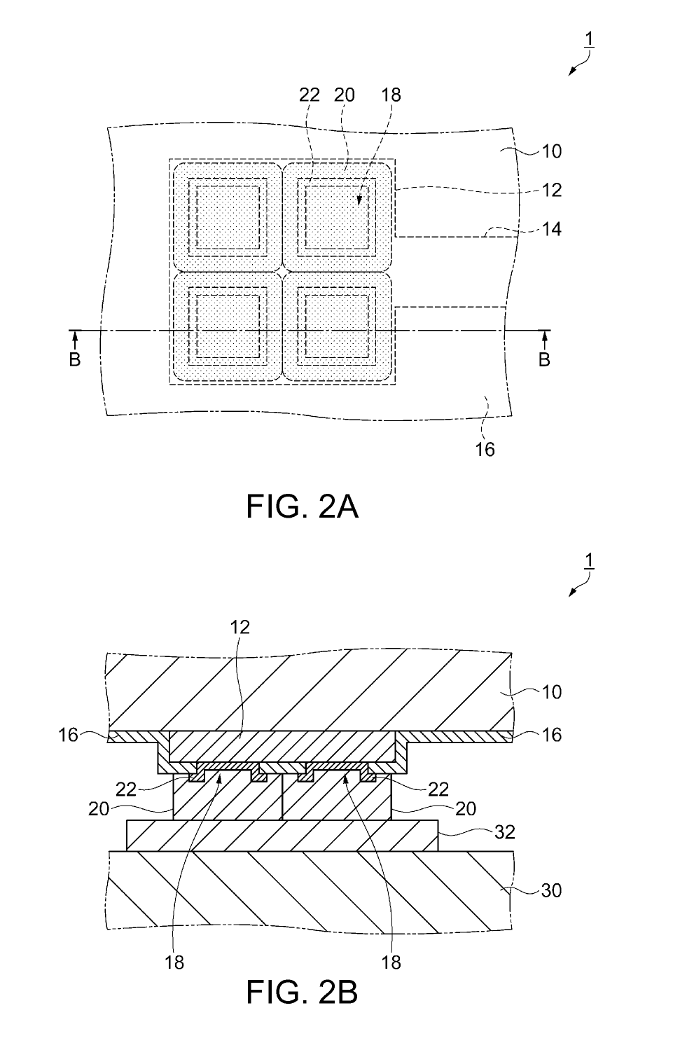

FIGS. 1A and 1B are schematic configuration diagrams of a pad portion provided on a circuit substrate of an electronic part according to a first embodiment of the invention. FIG. 1A is a plan view, and FIG. 1B is a cross-sectional view taken along the line A-A in FIG. 1A. FIGS. 2A and 2B are schematic configuration diagrams showing the pad portion in a state in which the circuit substrate of the electronic part according to the first embodiment of the invention is mounted on a mount substrate thereof. FIG. 2A is a plan view, and FIG. 2B is a cross-sectional view taken along the line B-B in FIG. 2A. FIG. 2A shows an electronic part 1 viewed in a see-through manner from the side of a circuit substrate 10 where no pad 12 is formed, and a mount substrate 30 and a pad 32 are omitted in FIG. 2A.

The electronic part 1 according to the first embodiment is formed of the circuit substrate 10, which is made, for example, of a semiconductor, and the mount substrate 30 bonded to each other via bumps 20, as shown in FIG. 2B. A portion of the pad 12 and therearound on the circuit substrate 10 includes the pad 12 formed on an active surface of the circuit substrate 10 and made, for example, of aluminum (Al), a lead portion 14 connected to the pad 12, a surface protection film 16 provided on the circuit substrate 10 and the pad 12, a barrier metal 22 formed through each opening 18 on the pad 12, and the bumps 20, the number of which is equal to the number of openings 18 and which are disposed on the pad 12.

The portion of the pad 12 and therearound on the circuit substrate 10 is bonded to a pad 32 provided on the mount substrate 30 by inverting the circuit substrate 10 upside down, placing the bumps 20 on the pad 32, compressing the bumps 20, and carrying out a thermocompression bonding process or an ultrasonic-assisted thermocompression bonding process, as shown in FIGS. 2A and 2B. The circumference of each of the bumps 20 in the state in which the circuit substrate 10 is bonded to the mount substrate 30 therefore widely spreads as compared with the circumference of the bump 20 before the bonding operation.

Among bonding conditions, when the circumference of each of the compressed bumps 20 extends off the region of the pad 12 by a width of 10 μm or smaller, the possibility of breakage of the surface protection film 16 has been experimentally proved to be small. The extend-off width of 10 μm or smaller therefore forms an acceptable range.

The plurality of openings 18 in the surface protection film 16 provided on the pad 12 are so disposed that one-half a length L1 of the shortest distance between the ends of adjacent openings 18 is smaller than a length L2 of the shortest distance from the outer circumferential edge of the pad 12 to the end of each of the openings 18. In the pad arrangement described above, when the circuit substrate 10 is bonded to the mount substrate 30, and even when each of the bumps 20 is so compressed in the compression bonding process that the outer circumference of the compressed bump 20 spreads and comes into contact with an adjacent bump 20, the outer circumference of the bump 20 does not come into contact with the outer circumferential edge of the pad 12, whereby a situation in which the bump 20 spreads to a portion close to the outer circumference of the pad 12 can be avoided. Since the compressed bumps 20 do not extend off the region of the pad 12 as described above, the surface protection film 16 will not be broken and a highly reliable electronic part 1 can be provided.

Further, a plurality of (three or more) openings 18 are provided in the surface protection film 16 on the pad 12 formed on the circuit substrate 10, and one bump 20 is formed in each of the openings 18. As a result, a plurality of bumps 20 are provided. Since the resistance to the passage of current due to a skin effect according to the circumferential length of each of the bumps 20 can therefore be reduced, the amount of loss in signal power in the bump 20 can be reduced. Further, the outer circumference of each of the bumps 20 is compressed and spreads to cover and protect the surface protection film 16, whereby the surface protection film 16 will not be broken due to external stress other than the stress produced in the compression bonding process.

Moreover, providing the plurality of openings 18 in the surface protection film 16 on the pad 12 and forming one bump 12 in each of the openings 18 allow stable bonding when the circuit substrate 10 is mounted on a mount substrate 30 having poor parallelism and flatness because the plurality of bumps 20 can compensate the poor parallelism and flatness of the mount substrate 30.

The bumps 20 are made of gold (Au) or a soldering material and formed in a method for forming a gold wire or a solder wire by using a bump bonder or by using electrolytic plating. Since the method using electrolytic plating allows single-step formation of bumps on a large substrate on which a plurality of circuit substrates 10 are formed, cost reduction is achieved as compared with the bump formation using a bump bonder.

The surface protection film 16, which protects the active surface of the circuit substrate 10, is made of SiO₂, SiN, or any other insulating material.

As described above, in the electronic part 1 according to the first embodiment of the invention, the plurality of openings 18 in the surface protection film 16 formed on the pad 12 and the bumps 20 each have a rectangular shape, but the shapes thereof are not limited to rectangular, and each of the openings and bumps may instead have a circular, elliptical, hexagonal, octagonal, or any other polygonal shape.

### Second Embodiment

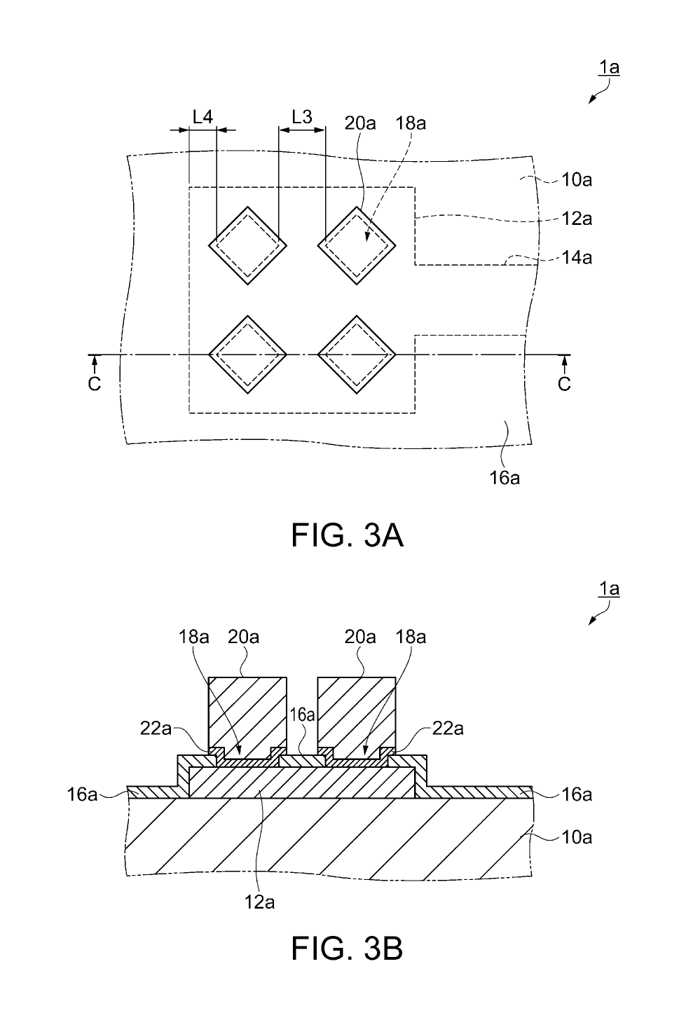

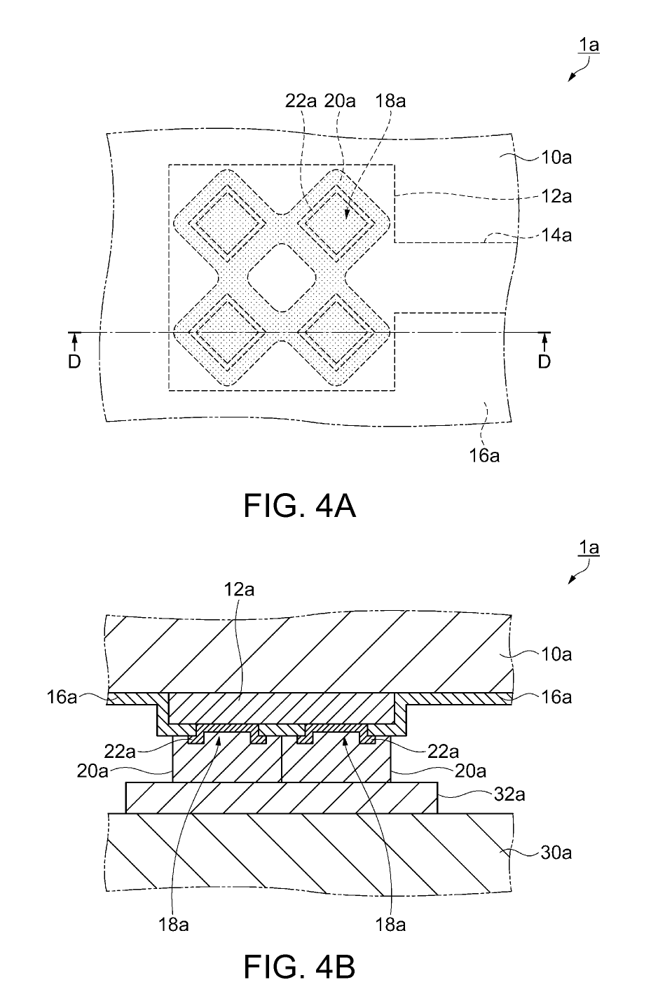

FIGS. 3A and 3B are schematic configuration diagrams of a pad portion provided on a circuit substrate of an electronic part according to a second embodiment of the invention. FIG. 3A is a plan view, and FIG. 3B is a cross-sectional view taken along the line C-C in FIG. 3A. FIGS. 4A and 4B are schematic configuration diagrams showing the pad portion in a state in which the circuit substrate of the electronic part according to the second embodiment of the invention is mounted on a mount substrate thereof. FIG. 4A is a plan view, and FIG. 4B is a cross-sectional view taken along the line D-D in FIG. 4A. FIG. 4A shows an electronic part 1a viewed in a see-through manner from the side of a circuit substrate 10a where no pad 12a is formed, and amount substrate 30a and a pad 32a are omitted in FIG. 4A.

In the following second embodiment, items different from those in the first embodiment described above will be primarily described, and the same items will not be described.

The portion of the pad 12a and therearound in the electronic part 1a according to the second embodiment, when compared with the portion of the pad 12 and therearound in the electronic part 1 according to the first embodiment, differs therefrom that the distance from corners of a plurality of openings 18a, and outer corner of barrier metals 22a and bumps 20a on a surface protection film 16a formed on the pad 12a to the outer circumferential edge of the pad 12a is minimized, as shown in FIGS. 3A and 3B.

Further, the plurality of openings 18a in the surface protection film 16a provided on the pad 12a are so disposed that one-half a length L3 of the shortest distance between the inner corners of adjacent openings 18 is smaller than a length L4 of the shortest distance from the outer circumferential edge of the pad 12a to the inner corners of each of the openings 18a.

In the electronic part 1a, even when each of the bumps 20a is so compressed in the compression bonding process that the outer circumference of the compressed bump 20a spreads and comes into contact with an adjacent bump 20a, the outer circumference of the bump 20a does not come into contact with the outer circumferential edge of the pad 12a, whereby a situation in which the bump 20a spreads to a portion close to the outer circumference of the pad 12a can be avoided, as shown in FIGS. 4A and 4B. Since the compressed bumps 20a therefore do not extend off the region of the pad 12a, the surface protection film 16a will not be broken.

Further, even when the outer circumference of each of the bumps 20a that are compressed and spread in the compression bonding process widely spreads, the bump arrangement in which the distance from the outer circumferential edge of the pad 12a to outer corner of inner corners of each of the openings 18a is minimized allows the portion of the bump 20a that extends off the region of the pad 12a to be only corners thereof and hence the amount of bump 20a that extends off to be reduced to a small value, as compared with the case where the distance from the outer circumferential edge of the pad 12 to the inner circumferential edge of each of the openings 18 is minimized as shown in the first embodiment. The degree of breakage of the surface protection film 16a can therefore be lowered, and hence a highly reliable electronic part 1a can be provided.

### Third Embodiment

An electronic part according to a third embodiment of the invention will next be described.

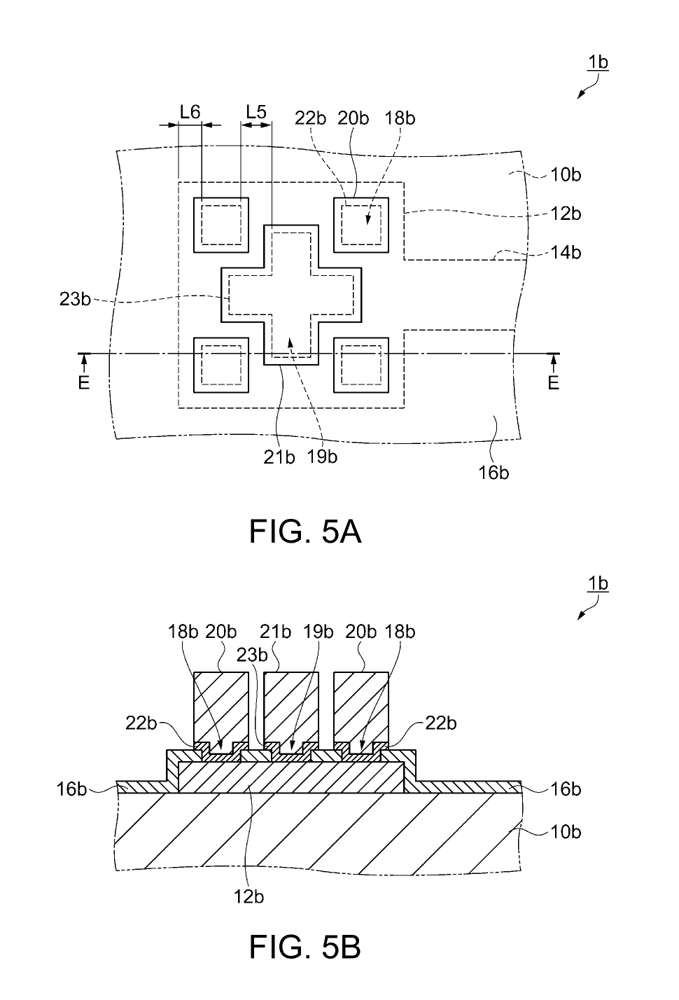

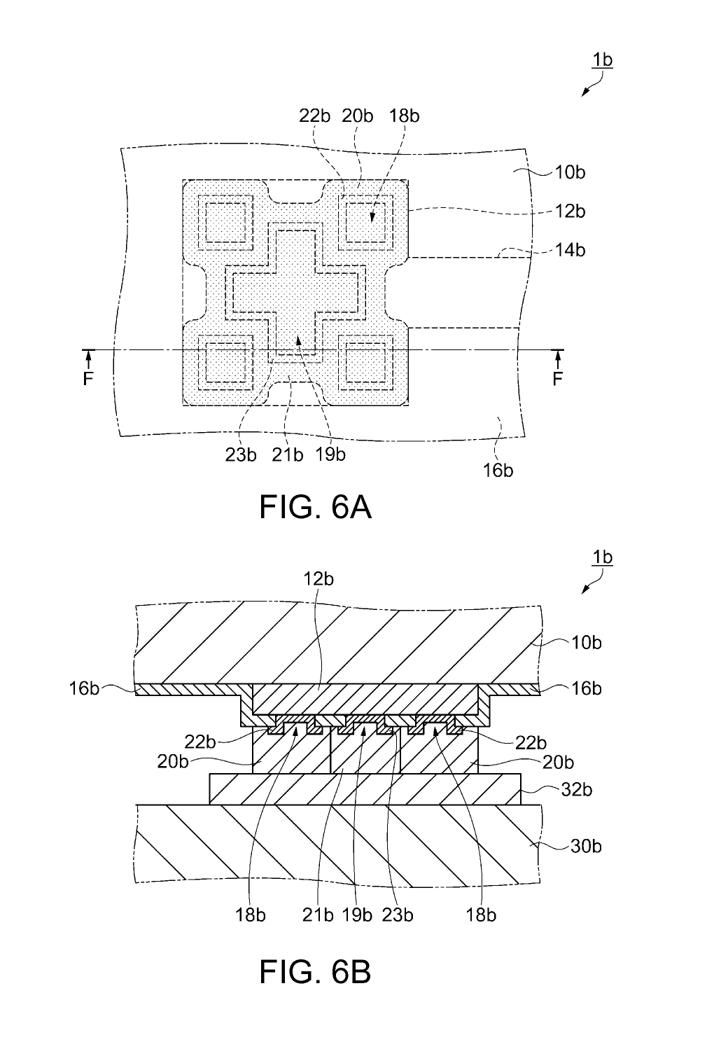

FIGS. 5A and 5B are schematic configuration diagrams of a pad portion provided on a circuit substrate of an electronic part according to a third embodiment of the invention. FIG. 5A is a plan view, and FIG. 5B is a cross-sectional view taken along the line E-E in FIG. 5A. FIGS. 6A and 6B are schematic configuration diagrams showing the pad portion in a state in which the circuit substrate of the electronic part according to the third embodiment of the invention is mounted on a mount substrate thereof. FIG. 6A is a plan view, and FIG. 6B is a cross-sectional view taken along the line F-F in FIG. 6A. FIG. 6A shows an electronic part 1b viewed in a see-through manner from the side of a circuit substrate 10b where no pad 12b is formed, and a mount substrate 30b and a pad 32b are omitted in FIG. 6A.

In the following third embodiment, items different from those in the first embodiment described above will be primarily described, and the same items will not be described.

The portion of the pad 12b and therearound in the electronic part 1b according to the third embodiment, when compared with the portion of the pad 12 and therearound in the electronic part 1 according to the first embodiment, differs therefrom that a cross-shaped opening 19b, a barrier metal 23b, and a bump 21b, which differ from openings 18b, barrier metals 22b, and bumps 20b in terms of size and shape, are disposed in a central portion of the pad 21b, as shown in FIGS. 4A and 4B.

Further, the plurality of openings 18b and 19b in a surface protection film 16b provided on the pad 12b are so disposed that one-half a length L5 of the shortest distance between the inner circumferential edge of each of the openings 18b and the inner circumferential edge of the opening 19b is smaller than a length L6 of the shortest distance from the outer circumferential edge of the pad 12b to the inner circumferential edge of each of the openings 18b.

In the electronic part 1b, the bumps 20b having a small size and formed in the openings 18b disposed in portions close to the four corners of the pad 12b are compressed but extend off the region of the pad 12b only by a small amount, whereby breakage of the surface protection film 16b due to the outer circumferences of the extend-off bumps 20b can be avoided, as shown in FIGS. 6A and 6B. On the other hand, the bump 21b having a large size and formed in the opening 19b disposed in the central portion of the pad 12b is compressed and the outer circumference of the bump 21b spreads widely but does not reach the outer circumference of the pad 12b, whereby the surface protection film 16b will not be broken and hence the bonding strength between the bumps 21b and the mount substrate 30b can be increased.

Further, when the bump 21b having a larger size formed in the opening 19b provided in the central portion of the pad 12b is compressed in the compression bonding process, the outer circumference of the compressed bump 21b spreads and comes into contact with the bumps 20b formed at the four corners. As a result, the compressed bumps 20b and 21b can cover broken pieces and other defective portions of the surface protection film 16b that are produced when the surface protection film 16b between the bumps 20b and the bump 21b is broken due to stress produced in the compression bonding process or other types of external stress, whereby the broken pieces of the surface protection film 16b are unlikely to be released outside and hence a highly reliable electronic part 1b can be provided.

### Fourth Embodiment

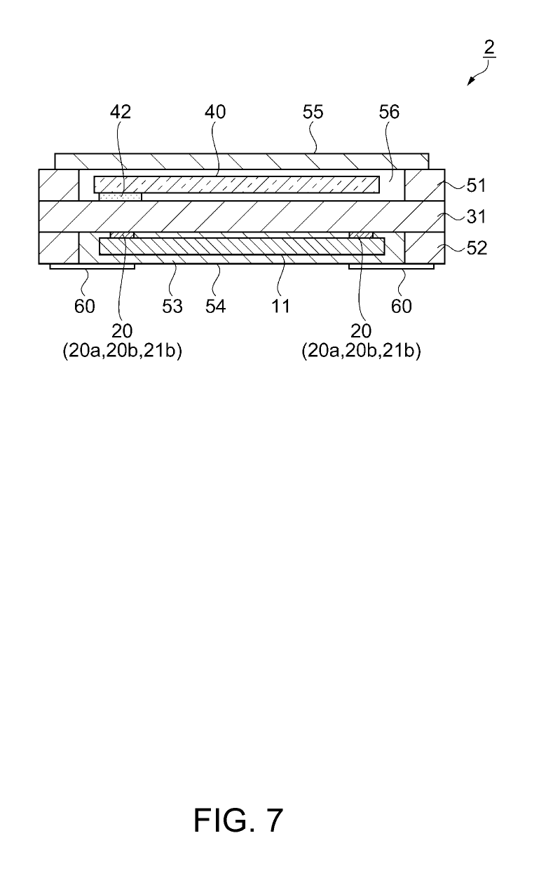

An oscillation device as an example of an electronic part according to a fourth embodiment of the invention will next be described. FIG. 7 is a cross-sectional view showing a schematic configuration of the oscillation device as an example of an electronic part according to the fourth embodiment of the invention. An oscillation device 2 as an example of an electronic part according to the fourth embodiment includes a circuit substrate 11, which forms an oscillation circuit, bumps 20 (20a, 20b, 21b), a mount substrate 31, and a resonator 40 as an resonator element, as shown in FIG. 7.

The circuit substrate 11, which forms an oscillation circuit, is configured, for example, as a single-chip semiconductor device. The oscillation circuit in the circuit substrate 11 includes the following two components: an oscillation section that uses the resonator 40 as a frequency source and has a feedback conductive path between the oscillation section and the resonator 40; and an impedance control section that controls the impedance between a path through which a signal is inputted from the oscillation section to the resonator 40 and a conductive path for electric power. Although not shown in FIG. 7, the mount substrate 31 has the following components provided therein: a wiring line and a terminal for electrically connecting the circuit substrate 11 and the resonator 40 to each other; a terminal through which an electric power potential is supplied to the oscillation circuit; a terminal through which an oscillation signal from the oscillation circuit is outputted; and other components.

The resonator 40 is disposed on the mount substrate 31. The resonator 40 has a base connected to the mount substrate 31 via a connection portion 42. The connection portion 42 is formed, for example, of a conductive adhesive and connects the resonator 40 to the mount substrate 31 and is electrically connected to an electrode disposed on the mount substrate 31 and then electrically connected to the circuit substrate 11. The resonator 40 can, for example, be an AT-cut, SC-cut, or any other type of quartz crystal resonator, a tuning fork resonator, a SAW (surface acoustic wave) resonator or any other piezoelectric resonator, or a MEMS (micro electro mechanical systems) resonator. The material of a substrate of the resonator 40 is not necessarily quartz crystal and may be a lithium tantalate, a lithium niobate, or any other piezoelectric single crystal, lead zirconate titanate or any other piezoelectric ceramic material, or a silicon semiconductor material. The resonator 40 may be excited based on a piezoelectric effect or electrostatic drive using a Coulomb force.

The bonding structure in the first, second, or third embodiment is used to mount the circuit substrate 11 on the mount substrate 31 in the oscillation device 2 according to the fourth embodiment. Although not shown in FIG. 7, the pad portion on the circuit substrate 11 includes the pad 12 (12a, 12b), the lead portion 14 (14a, 14b), the surface protection film 16 (16a, 16b), and the barrier metals 22 (22a, 22b, 23b) shown in FIGS. 2A and 2B (FIGS. 4A and 4B, FIGS. 6A and 6B). The mount substrate 31 includes the pad 32 (32a, 32b) shown in FIG. 2B (FIG. 4B, FIG. 6B). The circuit substrate 11 is bonded to the mount substrate 31 via the bumps 20 (20a, 20b, 21b).

A frame 52 is disposed on the mount substrate 31 on the side where the circuit substrate 11 is bonded thereto, and a recess 53 surrounded by the mount substrate 31 and the frame 52 is filled with a sealing member 54. Further, electrodes 60 are provided on the surfaces of the frame 52 and the sealing member 54. A frame 51 is disposed on the mount substrate 31 on the side where the resonator 40 is fixed thereto, and a lid 55, which covers a recess 56 surrounded by the mount substrate 31 and the frame 51, is provided. The resonator 40 is therefore accommodated in a space (recess 56) different from the space in which the circuit substrate 11 is accommodated.

According to the configuration of the oscillation device 2 in the fourth embodiment, since the bonding structure in the first, second, or third embodiment is used to mount the circuit substrate 11 on the mount substrate 31, a highly reliable oscillation device 2 that loses only a small amount of signal power in the bumps 20 (20a, 20b, 21b) is provided.

Electronic Apparatus

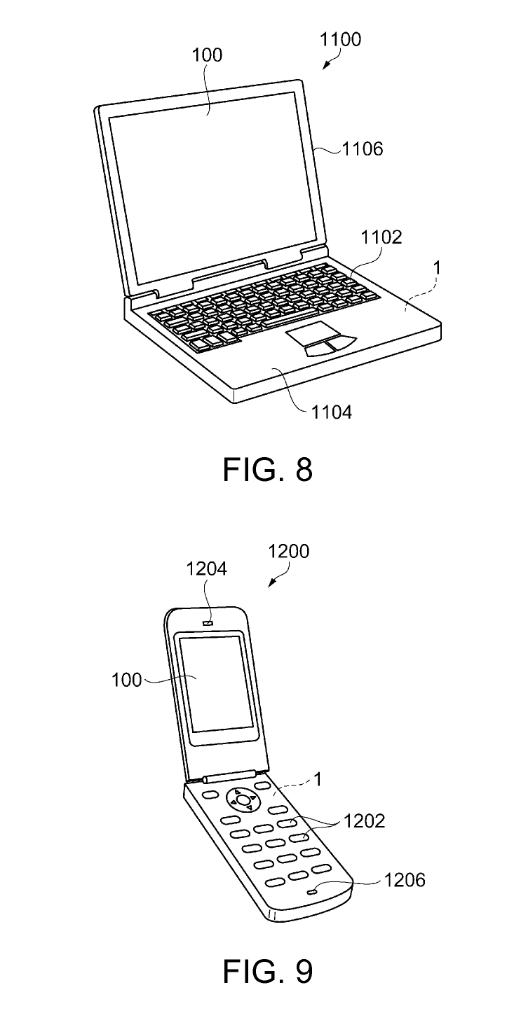

An electronic apparatus using any of the electronic parts 1, 1a, 1b, and 2 according to the embodiments of the invention will next be described in detail with reference to FIGS. 8 to 10.

FIG. 8 is a perspective view showing the configuration of a mobile (or notebook) personal computer as an electronic apparatus including the electronic part according to any of the embodiments of the invention. In FIG. 8, a personal computer 1100 is formed of the following components: a body 1104 including a keyboard 1102; and a display unit 1106 including a display section 100, and the display unit 1106 is so supported by the body 1104 via a hinge structure that the display unit 1106 is pivotal relative to the body 1104. The thus configured personal computer 1100 accommodates any of the electronic parts 1, 1a, 1b, and 2.

FIG. 9 is a perspective view showing the configuration of a mobile phone (including PHS) as an electronic apparatus including the electronic part according to any of the embodiments of the invention. In FIG. 9, a mobile phone 1200 includes a plurality of operation buttons 1202, a receiver 1204, and a transmitter 1206, and a display section 100 is disposed between the operation buttons 1202 and the receiver 1204. The thus configured mobile phone 1200 accommodates any of the electronic parts 1, 1a, 1b, and 2.

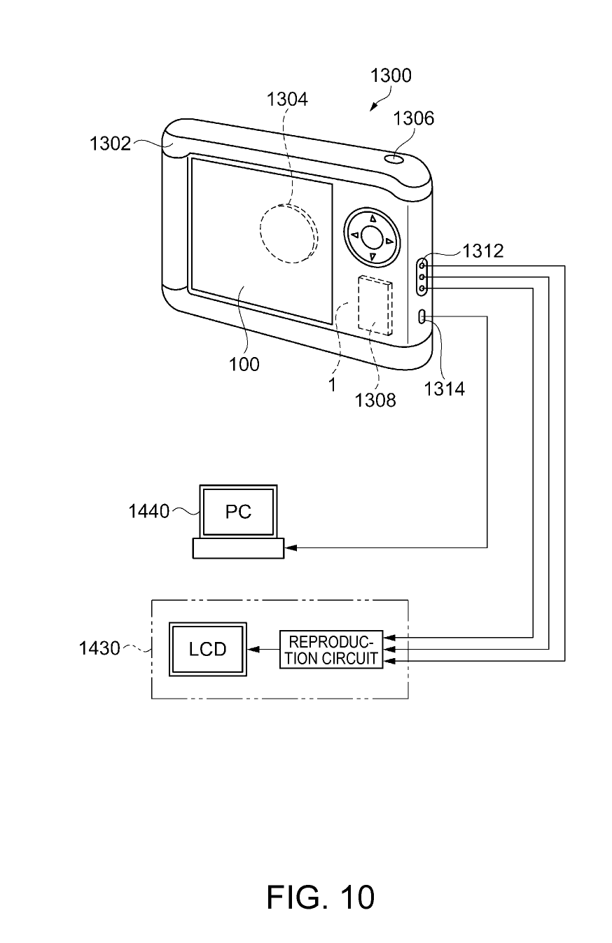

FIG. 10 is a perspective view showing the configuration of a digital camera as an electronic apparatus including the electronic part according to any of the embodiments of the invention. FIG. 10 also schematically shows connection to external apparatus. In a typical camera, a silver photographic film is exposed to light, specifically to an optical image of a subject, whereas a digital camera 1300 converts an optical image of a subject into a captured image signal (image signal) in a photoelectric conversion process by using a CCD (charge coupled device) or any other imaging device.

A display section 100 is provided on the rear side of a case (body) 1302 of the digital camera 1300 and displays an image based on the captured image signal from the CCD. The display section 100 thus functions as a finder that displays a subject in the form of an electronic image. Further, alight reception unit 1304 including an optical lens (imaging system), the CCD, and other components is provided on the front side (rear side in FIG. 10) of the case 1302.

When a user of the camera checks a subject image displayed on the display section 100 and presses a shutter button 1306, a captured image signal from the CCD at that point of time is transferred to and stored in a memory 1308. Further, in the digital camera 1300, a video signal output terminal 1312 and a data communication input/output terminal 1314 are provided on a side surface of the case 1302. The video signal output terminal 1312 is connected to a television monitor 1430 as necessary, and the data communication input/output terminal 1314 is connected to a personal computer (PC) 1440 as necessary, as shown in FIG. 10. Further, in response to predetermined operation, the captured image signal stored in the memory 1308 is outputted to the television monitor 1430 or the personal computer 1440. The thus configured digital camera 1300 accommodates any of the electronic parts 1, 1a, 1b, and 2.

An electronic apparatus including any of the electronic parts 1, 1a, 1b, and 2 according to the embodiments of the invention is used not only in the personal computer 1100 shown in FIG. 8, the mobile phone 1200 shown in FIG. 9, and the digital camera 1300 shown in FIG. 10 but also, for example, in a smartphone or any other mobile terminal, a communication device, an inkjet-type liquid ejection apparatus (inkjet printer, for example), a laptop personal computer, a tablet personal computer, a router, a switch, or any other storage area network apparatus, a local area network apparatus, an apparatus for a mobile terminal base station, a television receiver, a video camcorder, a video recorder, a car navigation system, a realtime clock apparatus, a pager, an electronic notebook (including electronic notebook having communication capability), an electronic dictionary, a desktop calculator, an electronic game console, a word processor, a workstation, a TV phone, a security television monitor, electronic binoculars, a POS terminal, a medical apparatus (such as electronic thermometer, blood pressure gauge, blood sugar meter, electrocardiograph, ultrasonic diagnostic apparatus, and electronic endoscope), a fish finder, a variety of measuring apparatus, a variety of instruments (such as instruments in vehicles, airplanes, and ships), a flight simulator, a head-mounted display, a motion tracer, a motion tracker, a motion controller, and a PDR (pedestrian dead reckoning).

### Moving Object

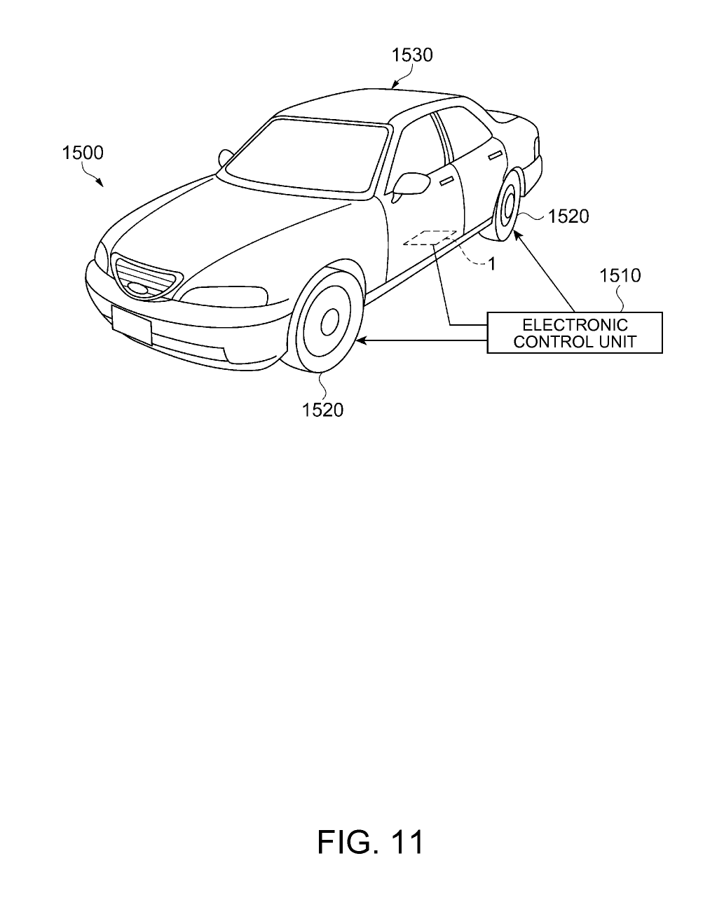

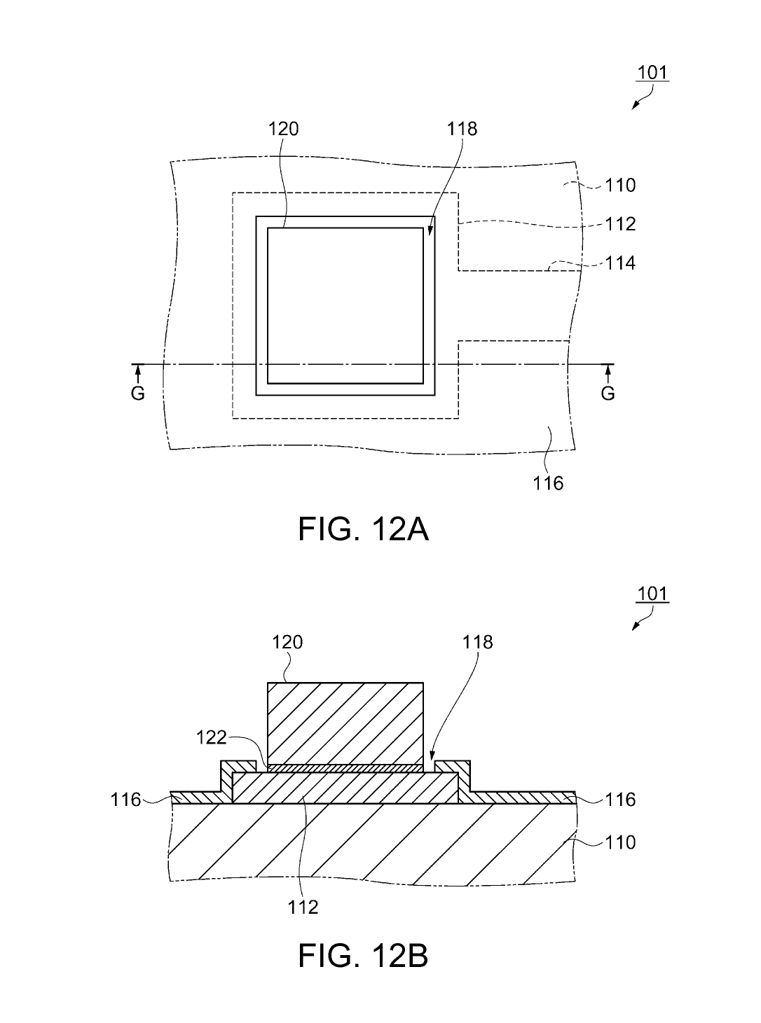

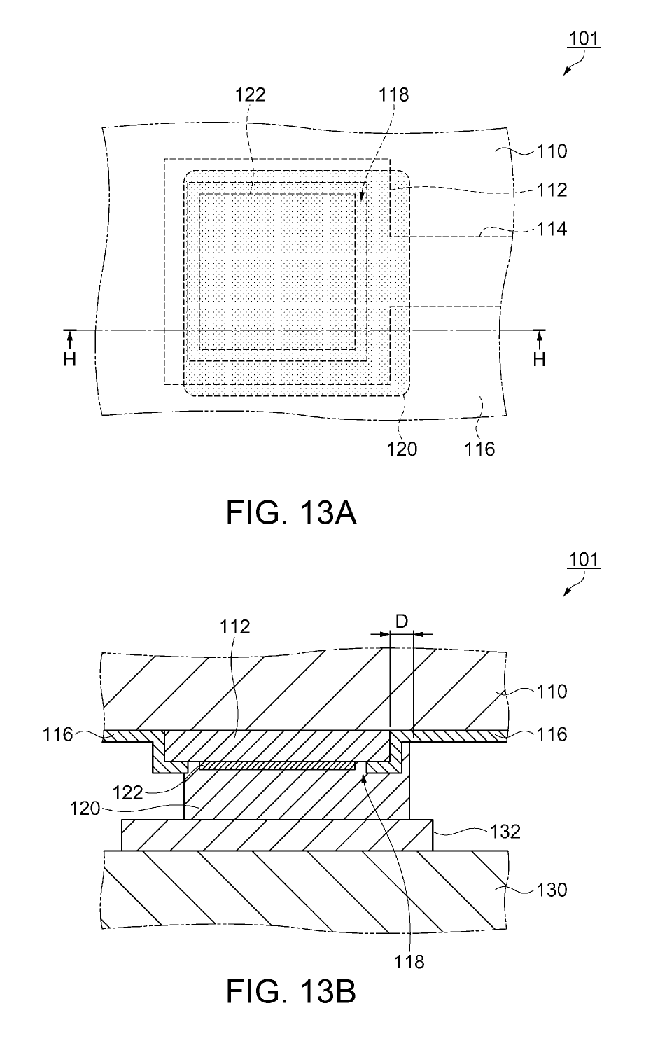

FIG. 11 is a perspective view schematically showing an automobile as an example of a moving object. An automobile 1500 accommodates any of the electronic parts 1, 1a, 1b, and 2 according to the embodiments of the invention. For example, the automobile 1500 as a moving object, specifically, a vehicle body 1530 accommodates an electronic control unit 1510, which accommodates any of the electronic parts 1, 1a, 1b, and 2 and controls wheels 1520 and other components, as shown in FIG. 11. In addition, any of the electronic parts 1, 1a, 1b, and 2 according to the embodiments of the invention can be widely used as a keyless entry system, an immobilizer, a car navigation system, a car air conditioner, an antilock brake system (ABS), an airbag, a tire pressure monitoring system (TPMS), an engine control system, a brake system, an apparatus that monitors a battery in a hybrid automobile and an electric automobile, a vehicle body attitude control system, and any other electronic control unit (ECU).

The electronic parts, the electronic apparatus, and the moving object according to the embodiments of the invention have been described with reference to the drawings, but the invention is not limited thereto and the configuration of each component can be replaced with an arbitrary configuration having the same function. Further, any other arbitrary component may be added to the embodiments of invention. Moreover, the embodiments may be combined with each other as appropriate.

The entire disclosure of Japanese Patent Application Nos. 2013-110615, filed May 27, 2013 and 2014-054495, filed Mar. 18, 2014 are expressly incorporated by reference herein.

What is claimed is:

1. An electronic part comprising:
a mount substrate;
a circuit substrate;
a pad disposed on the circuit substrate;
a bump that connects the mount substrate and the pad to each other; and
a surface protection film that extends from a surface of the pad via an outer circumferential edge of the pad to a surface of the circuit substrate and has at least two openings adjacent to each other on the pad,
wherein the length equal to one-half the shortest distance from an end of one of the adjacent openings to an end of the other opening is smaller than the shortest distance from the outer circumferential edge of the pad to the end of each of the openings, and
the bump is provided in each of the two openings and layered on the surface protection film in a plan view.

2. The electronic part according to claim 1,
wherein the bumps have a rectangular shape and are so arranged that the distance between the outer circumferential edge of the pad and a corner of each of the openings is minimized.

3. The electronic part according to claim 1,
wherein the bumps are provided in a plating process.

4. The electronic part according to claim 1,
wherein the bumps adjacent to each other are in contact with each other.

5. The electronic part according to claim 1,
wherein the openings have sizes different from each other.

6. The electronic part according to claim 1,
wherein the openings are located in at least three positions.

7. The electronic part according to claim 1, further comprising an resonator element,
wherein the resonator element is disposed on the mount substrate and electrically connected to the circuit substrate.

8. An electronic apparatus comprising the electronic part according to claim 1.

9. A moving object comprising the electronic part according to claim 1.
